(19) United States
(12) Patent Application Publication
(10) Pub. No.: US 2019/0127212 A1
(43) Pub. Date: May 2, 2019

(54) FORMING A PASSIVATION COATING FOR MEMS DEVICES

(71) Applicant: TEXAS INSTRUMENTS INCORPORATED, Dallas, TX (US)

(72) Inventors: Simon Joshua JACOBS, Lucas, TX (US); Molly Nelis SING, Murphy, TX (US); Lawrence Tucker LATHAM, Plano, TX (US)

(21) Appl. No.: 15/799,808

(22) Filed: Oct. 31, 2017

(51) Int. Cl. B81B 3/00; B81C 1/00

(52) U.S. Cl. CPC B81B 3/0005; B81C 2201/0176; B81C 1/00984

(57) ABSTRACT

In described examples, a MEMS device component includes a passivation layer formed from a vapor and/or a liquid compound that may include precursors. The compound may contain amino acid, antioxidants, nitriles or other compounds, and may be disposed on a surface of the MEMS device component and/or a package or package portion thereof. If the compound is a precursor, it may be treated to cause formation of the passivation layer from the precursor.

### BACKGROUND

Microelectromechanical system (MEMS) devices (such as actuators, switches, motors, sensors, variable capacitors, spatial light modulators (SLMs) and similar microelectronic devices) can have movable elements. For example, a typical SLM device includes an array of movable elements in the form of individually addressable light modulator elements, whose respective “on” or “off” positions are set in response to input data to either pass or block transmission or reflectance of light directed at the array from an illumination source. For an SLM device in an image projection system, the input data corresponds to bits of bit frames generated from pixel hue and intensity information data of an image frame of an image input signal. The bit frames may be compilations of bits in a pulse-width modulation scheme that uses weighted time segment “on” or “off” periods for generation of corresponding pixel hue and intensity by eye integration during a given available image frame display period. A representative example of an SLM device includes a digital micromirror device (DMD), such as a Texas Instruments DLP™ micromirror array device. DLP™ devices have been employed commercially in a wide variety of products, such as televisions, cinemagraphic projection systems, business-related projectors and picoprojectors.

The mechanical performance of the moving elements within a MEMS device can be compromised by unintended adhesion. This type of adhesion can be reduced by coating contacting elements of the MEMS device with a coating, such as a passivating agent or lubricant. The coating can be added to address several problems with device operation. One such problem is static friction (stiction). Another problem can include dynamic friction, which arises from the contact of moving elements in the device. Effective coatings can aid in reducing stiction and dynamic friction by reducing the surface energy of the device. For rotating devices (such as a micromirror supported for rotation on a hinge in a DMD), repeated movement displaces atoms and/or molecules and permanently biases the zero state of the rotation. Passivation layers may reduce this hinge memory accumulation by stabilizing certain states of the surface.

### SUMMARY

In described examples of a method of manufacturing a MEMS device, the method comprises: exposing a first MEMS device component to a vapor; and forming, subsequent to the vapor exposure, a passivation layer on at least one exposed surface of the component, wherein the vapor comprises a material having a bulk dielectric constant of at least 4.02.

In further examples of a method of manufacturing a MEMS device, the method comprises: exposing a MEMS device component to a vapor; and forming, subsequent to the vapor exposure, a passivation layer on at least one exposed surface of the MEMS device component, wherein the passivation layer comprises a component comprising at least one amino acid.

In more examples of a method of manufacturing a MEMS device, the method comprises: disposing a precursor in contact with at least a portion of a surface of a MEMS device component, wherein the precursor comprises a long-chain alcohol of at least 12 carbons; establishing an equilibrium distribution of the precursor on the surface of the MEMS device component; treating the MEMS device component; and forming a passivation layer on the surface of the MEMS device component, wherein the precursor is transformed into the passivation layer in response to the treating, and the passivation layer is formed on the surface of the MEMS device component comprising the precursor.

In additional examples of a method of manufacturing a MEMS device, the method comprises: exposing at least one contact surface of a MEMS device component to an organic compound comprising at least one ionic region and at least one hydrophobic region; actuating the vapor in contact with the at least one contact surface of the MEMS device component; and forming, in response to the actuation, a passivation film on the at least one contact surface.

In other described examples, a MEMS device comprises: a MEMS component comprising a surface; and a passivation layer on at least a portion of the surface, wherein the passivation layer comprises a compound comprising an alkyl nitrile.

In alternative examples of a method of manufacturing a MEMS device, the method comprises: exposing a MEMS device component to a vapor; and forming, subsequent to the vapor exposure, a passivation layer on at least one exposed surface of the MEMS device component, wherein the passivation layer comprises at least one antioxidant compound.

### BRIEF DESCRIPTION OF THE DRAWINGS

FIG. 1 is a partial side sectional view of a MEMS device component fabricated according to example embodiments.

FIG. 2 is a flow chart of a method of forming a passivation layer on a MEMS device component according to example embodiments.

FIGS. 3A through 3C are a sequence of partial side sectional views of a MEMS device component during fabrication according to the method of FIG. 2.

FIG. 4 is a flow chart of a first alternative method of forming a passivation layer on a MEMS device component.

FIGS. 5A through 5E are a sequence of partial side sectional views of a MEMS device component during fabrication according to the method of FIG. 4.

FIG. 6 is a flow chart of a second alternative method of forming a passivation layer on a MEMS device component.

FIGS. 7A through 7E are a sequence of partial side sectional views of a MEMS device component during fabrication according to the method of FIG. 6.

FIGS. 8A and 8B are perspective views of a first MEMS device component fabricated according to example embodiments.

FIGS. 9A and 9B are perspective views of a second MEMS device component fabricated according to example embodiments.

### DETAILED DESCRIPTION

On a micrometer or smaller scale, atomic level and microscopic level forces between surfaces in contact become significant. Problems related to these types of forces are accordingly relevant to micromechanical devices, such as microelectromechanical system (MEMS) and nanoelectromechanical system (NEMS) devices. A MEMS device includes one or more MEMS elements in addition to other elements. For example, “stiction” forces (created during operation between moving parts that contact each other, either intentionally or accidentally) can be a problem with micromechanical devices. Stiction-type failures occur when the interfacial attraction forces (created between moving parts that come into contact with one another) exceed restoring forces. Stiction can cause surfaces of these parts to either permanently or temporarily adhere to each other, causing device failure and/or malfunction. Stiction forces are complex surface phenomena that generally include capillary forces, van der Waals forces, and electrostatic attraction forces. As used herein, the term “contact” refers generally to any interaction between two surfaces and is not limited to the actual physical touching of the surfaces. Examples of micromechanical devices and/or devices including semiconductor components are: RF switches, optical modulators, microgears, accelerometers, worm gears, transducers, fluid nozzles, gyroscopes and other similar devices or actuators. In this description, the term “MEMS” device or component generally describes a micromechanical device, and includes both MEMS and NEMS devices.

MEMS and/or semiconductor components, which can experience repeated physical contact between moving parts, may use a coating compound for lubrication to reduce or prevent stiction and/or dynamic friction. Various elements in these devices often interact with each other during operation at frequencies between a few hertz (Hz) and a few gigahertz (GHz). Without adding some form of lubrication to these types of devices to reduce stiction and wear between component surfaces, product lifetimes may range from only a few contacts to a few thousand contacts, which is generally well below a commercially viable lifetime.

In MEMS manufacturing, conventional techniques may focus on modifying an oxide surface of a MEMS element with an organic material. Such organic material may bind or interact directly with the metal oxide or metal surface of the MEMS element. In contrast, at least some example embodiments described herein are directed towards using a compound in a carrier solvent, and forming a film in areas of contact on a MEMS device (which includes at least one MEMS element). MEMS elements and devices that include MEMS elements, such as radio frequency MEMS (RFMEMS) devices, may be actuated via contact interfaces, which can degrade as a consequence of water accumulated during the manufacturing, assembly and/or testing process. The film described herein acts to reduce surface energy at the contact interfaces and to provide a medium that can moderate the occurrence of deleterious reactions by stabilizing charge across a wider potential range than adsorbed water. The film(s) adsorbed herein may be referred to as: (a) “surface” film(s), because it forms on exposed areas of a MEMS device; or (b) “passivation” film(s) or layer(s) based upon the film's functionality. These exposed areas may be referred to as parts of a substrate or an exposed surface. Conventional methods may use acidic passivation, in contrast to ionic compounds, organic compounds including at least one ionic region and at least one hydrophobic region, long-chain alcohols, and/or amino acids described herein and used in example embodiments. The films and layers described herein are collectively referred to as “compounds” or “coating compounds.”

MEMS elements and MEMS devices (which include more than one MEMS element) may be manufactured and enclosed in a package. The films, layers and compounds described herein may be applied directly to MEMS elements via solution and/or vapor, or may be deposited in MEMS packaging during the packaging process, before sealing the package. The compounds described herein may act as passivation layers, and may be formed upon the vapor or solution coming into contact with the MEMS device. In some examples, the compounds are disposed as a precursor that transforms into a passivation layer. This transformation may occur in response to heat and/or exposure to light or electrical fields. The application of heat may be in the form of an annealing step or steps, or by an actuation of the device itself. In some examples, an equilibrium distribution of the vapor or solution deposited may be formed via the deposition and packaging/sealing process, and the film acts as a passivation layer formed on the exposed surfaces of the MEMS device.

In some examples, the surfaces of an RF MEMS device are treated with an ionic organic compound and can mitigate or eliminate: (a) charge accumulation during operation; and (b) stiction and wear by lowering the surface energies of the contacting surfaces. During operation of the device, such as during device testing, these undesirable effects may be mitigated by the use of organic compounds that have ionic moieties and non-ionic moieties or regions. In further examples, the non-ionic regions can form hydrophobic portions or properties within the molecules. In at least one example, organic compounds that exhibit all of this functionality include hydrophobic amino acids, both natural and unnatural, which exhibit a zwitterionic structure in the solid state. For example, treatment of an RF MEMS device with L-leucine is useful to extend the device's service lifetime by three or more orders of magnitude. In some examples, N-alkyl glycines may also be employed. The treatment that introduces the organic compounds to the MEMS device may occur during manufacture of the MEMS elements and/or during the packaging (sealing) process.

In at least one example, a MEMS device includes a film of an organic compound having an ionic structure that may be deposited as a partial monolayer, a monolayer or as a multilayer structure. In a further example, a MEMS device includes a film of an organic compound including at least an ionic region and at least one hydrophobic region. The film may be deposited as a partial monolayer, monolayer or as a multilayer structure. In yet another example, a MEMS device includes a film of an organic compound including at least an ionic region, a hydrophobic region and a polymeric structure that can be present upon deposition and/or formed during the deposition of the film, where the film is formed as a partial monolayer, a monolayer or as a multilayer structure.

In some examples, MEMS devices may be treated with the vapor of an organic compound, which may react in situ with other reactants or the environment to form an organic ionic compound film. In one example, more than one organic compound may be employed, and each compound employed to form the film can include at least an ionic region and a hydrophobic region. In further examples, a polymer of the organic compound or compounds is formed on the MEMS device. In an alternative example, a solution of at least one organic compound or polymer (including at least an ionic region and a hydrophobic region) may be used to form a film on the MEMS device. The films described herein may be formed as a partial monolayer, a monolayer or as a multilayer structure.

In another example, the surfaces of an RF MEMS device can be treated with an alcohol, such as a long-chain organic alcohol, which can delay the onset of wear and stiction (caused by operation) by lowering the surface energies of the contacting surfaces. This mitigation of deleterious effects may be executed through the use of long-chain organic alcohols. The use of long-chain organic alcohols may increase the manufacturability and decrease the cost of manufacture of MEMS devices including the film. In some examples, the use of long-chain alcohols may also prevent aggregation of a variety of particles resulting from operation, and thereby slow or stop degradation of device parameters. Long-chain alcohols employed in an example process may include primary alcohols with at least 12 carbons, in which the carbon chain is straight or branched. Branched chain alcohols may provide a wider liquid temperature range during the application process. For example, the long-chain alcohol may contain one or more heteroatoms (such as a polyol). The treatment of a particular RF MEMS device with cetyl alcohol can extend the service lifetime of the device by three or more orders of magnitude.

In at least one example, a MEMS device includes a film of one or more alcohols containing 12 to 40 carbons, with or without secondary branching, and which may contain heteroatoms in its carbon chain(s). The alcohol(s) can be primary alcohols. The alcohol film may have a partial monolayer, monolayer or multilayer structure. This film of an organic alcohol contains 12 to 40 carbons, with or without secondary branching, and may contain heteroatoms in its carbon chain(s) on the surfaces of a MEMS device. The film may be formed via: (a) deposition by adsorption from a solution in a solvent or supercritical liquid; (b) vapor deposition at a temperature substantially above room temperature; or (c) in-situ polymerization of a suitable precursor on the surface of the MEMS device. The compound may be disposed on a MEMS device component (such as a MEMS wafer, a cap or other non-MEMS wafer) and/or a packaging component, such that an equilibrium distribution of the compound is achieved either during sealing of the wafers and/or during the enclosure of the sealed wafers in the package.

In another example, antioxidants may be used to form the coating. Antioxidants are organic compounds that serve to chemically stabilize and spatially delocalize unpaired electrons, also known as free radicals. Antioxidants may accomplish their function through steric hindrance, electronic delocalization, or a combination of these effects. Example antioxidants include several naturally occurring compounds, such as resveratrol, vitamin C, vitamin K, vitamin E, etc. Artificial antioxidants include butylated phenols, such as 2,6-di-t-butyl-4-methylphenol (BHT) (steric hindrance), triarylamine dyes and/or their precursors (electronic delocalization), oligothiophenes, oligo(phenylenevinylenes), polyunsaturated hydrocarbon polymers, fatty acids containing polyunsaturated side chains, etc. When suitably applied to the MEMS device, antioxidant compounds from these families serve to extend (by two to five orders of magnitude) the durability of the MEMS device in terms of contact lifetime. Without hewing to a specific mechanism of action, the delocalization of charges instantaneously formed upon device actuation serves to prevent or delay the onset of deleterious mechanochemical or electrochemical reactions that may occur in the absence of such compounds.

In some examples, the exposed surfaces of an RF MEMS device may be treated with fluorine-containing vapor or plasma, followed sequentially by an organic molecule or monomer selected to form a film that may increase the reliability of the device, such as by forming a passivation layer. For example, plasma treatment may result in surface fluorination. The increased stability may be due in part to improved attraction/surface adhesion caused by the acid-base interaction, and also may be at least partially due to polymerization of the organic material initiated by the acidic surface. MEMS devices can exhibit improved operational lifetimes, because the surface films (formed using the plasma treatment) may prevent or delay the wear processes (encountered between contacting device surfaces) that occur in the absence of forming this film. Accordingly, in some examples, the formation of this film may increase a MEMS device lifetime by an order of two or more.

For example, a MEMS device may undergo a treatment where a metal oxide (contact) surface is exposed to a halogen-containing plasma to give a surface with greater Lewis acid characteristics. This exposure may be followed by contact with a basic organic molecule or monomer to improve attraction between the surface and the organic material and/or the polymerization of the organic material due to the enhanced acidic nature of the surface. In a further example, the formation of (cyclic) lactams leads to suitable passivation films when exposed to the surfaces. Some compounds that may be employed include N-methyl pyrrolidinone (N-methyl butyrolactam) and N-octyl pyrrolidinone (N-octyl butyrolactam). Other monomers (which may be suitable to form complexes with and/or polymers on the acidic surfaces) include: (cyclic) lactones, thiolactones, dithiolactones, thiolactams, alkenes, alkynes, nitriles & isocyanates.

Thin passivating films may be formed in situ on the surfaces of MEMS devices through inclusion of a small amount of certain solvents within the device package. These solvents may act (or may have the effects enhanced) due to capillary condensation of the solvent per the roughness and asperities of the contacting surfaces. The passivating film may also: (a) lower energy between contacting surfaces due to shielding of van der Waals interactions between the surfaces; and/or (b) serve to expand the bulk electrochemical window or potential difference between surfaces that may be tolerated without significant degradation. In some examples, for treatment of the surfaces of a MEMS device, and/or for inclusion of a compound in a MEMS device package, a solvent or solvent mixture includes: (a) a bulk dielectric constant at least 5% of that of water, and ideally a bulk dielectric constant at least 50% of that of water or more; (b) a bulk electrochemical window similar to or greater than that of water, usually from 1.5 volts vs. SCE anodic to −2.0 volts vs. SCE cathodic; (c) a melting point similar to or lower than that of water (273 K); (d) a boiling point similar to or greater than that of water (373 K); and/or (5) a surface tension less than or equal to that of water and a solubility suitable for both organic and inorganic ions.

Solvents employed for treatment may include benzonitrile, various alkyl nitriles, sulfolane, other alkyl sulfones and/or sulfoxides, N-methyl-2-pyrrolidinone, other lactams, amides (such as dimethyl formamide and dimethyl acetamide), alkyl carbonates (such as propylene carbonate), and ethylene glycol or ethylene-oxide polyethers, including those with bis(alkyl) termination.

These chemical solvents may be included in the MEMS package, such as by vapor delivery of the solvent, or via immersion of one or more package or device surfaces into a solution containing the desired chemical before a sealing step. They may also be included indirectly, via inclusion of a precursor chemical by one of these methods, which may later be transformed into a suitable chemical via chemical reactions that are electrochemical, photochemical, or thermal in nature.

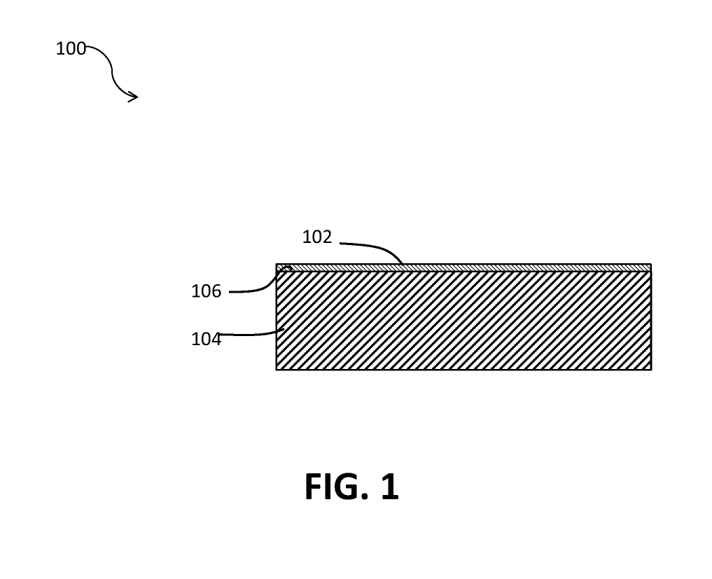

FIG. 1 is a partial side sectional view 100 of a MEMS device component 104 fabricated according to example embodiments. As shown in FIG. 1, a passivation coating 102 described herein may be applied directly or in the form of a precursor to coat at least a portion of a surface 106 of a MEMS or other semiconductor component 104. In one example, the precursor may contact a surface 106, interact with the surface 106, and form a passivation coating 102 on the component 104. The passivation coating 102 may be formed on the component 104 where the precursor is disposed, upon contact with the surface 106 or after a predetermined amount of time after exposure to the precursor. In other examples, the formation of the passivation coating 102 may occur when the precursor is disposed on the component 104, or subsequently in response to a thermal, photochemical or electrochemical process. These processes may include annealing, device actuation and/or exposure to light or radiation. In another example, the precursor or compound is disposed in contact with a portion of a package (not shown) of the MEMS component 104, and the passivation coating 102 is formed on the component 104 and other components in the package when the component 104 is enclosed in the package.

For example, the coating compounds to form the passivation coating 102 may have a chemisorption interaction with the surface 106. The interaction of a precursor with the surface 106 may allow the precursor to form a relatively thin coating on the surface 106, which may include an ordered array of molecules, as described in more detail herein. The coating compounds described herein may be useful with a MEMS or semiconductor component 104 having a functionality characterized by intermittent surface-to-surface contact of mechanical elements (such as in DMDs, microactuators or devices with similarly relatively movable elements), a continuous surface-to-surface sliding contact of mechanical elements (e.g., in a micromotor, microactuator or similarly operating device), a functionality derived through the controlled surface energy of the surfaces on elements (such as in a sensor or equivalent device), a functionality derived through the protection or passivation of the surfaces on elements (such as in a sensor or equivalent device), and/or a functionality derived through the dielectric properties of the surfaces on elements (such as in a variable capacitor, microswitch, or equivalent device). The precursor may also be useful in other situations where a modified surface is part of any device or machine that benefits from having functional surfaces coated with a hydrophobic passivant or lubricant. Suitable MEMS and/or semiconductor components 104 may include radio frequency (RF) switches, optical modulators (e.g., SLMs), microgears, accelerometers, worm gears, transducers, fluid nozzles, gyroscopes and other similar devices or actuators.

In at least one example, a MEMS device may include a digital micromirror device (DMD), such as a Texas Instruments Incorporated DLP™ micromirror device. The DMD generally includes a mirror/yoke assembly configured to rotate on a torsion hinge until the yoke tips contact (lands on) landing pads. In some cases, the mirror/yoke assemblies become slow in lifting off the landing pad, affecting the response of the device. In other cases, the assemblies become permanently stuck to the landing pads. The primary causes of stiction include scrubbing of the landing tips into the metal landing pads. The stiction problem may be addressed by coating or passivating the metal surfaces of the devices with any of the coating compounds described herein. The coating compound(s) may tend to decrease the van der Waals forces associated with the mirror assemblies in the DMD or any moving parts in a MEMS device, and thereby reduce the tendency for the mirrors to stick to the landing pads.

For example, a MEMS and/or semiconductor component may be incorporated into a larger assembly or package. The coating compound may be disposed over a portion of the MEMS and/or semiconductor component before disposing the component in the package, or the package (including the MEMS and/or semiconductor component) may be coated with the coating compound before being sealed. Such packages may retain the coating compound, protect against contaminants (such as dust and moisture), and generally protect the MEMS and/or semiconductor component.

In at least one example, a DMD may be incorporated into a device package. The package may include a frame and a lid, such as cover glass. The cover glass can be opaque on the underside with a transparent aperture for optical interfacing with the device. As described hereinabove, the stiction problem has usually been addressed by attempting to control the environment inside the packages. For example, the coating compound can be disposed on the DMD within the package and then sealed to retain the coating compound within the package. As described in more detail herein, the coating compound may exist as a thin layer of liquid in equilibrium with a vapor. The package may then act to contain the MEMS and/or semiconductor device, and also to retain the coating compound within the package. The coating compound may be in a solid or liquid state, depending on the properties of the material and the temperature and pressure or environment in which the coating compound is placed. Generally, the terms “solid” or “liquid” coating compound refer to a compound that is in a solid or liquid state under ambient conditions, i.e., room temperature and atmospheric pressure. The term “vapor” phase coating compound generally describes a mixture of components that contain a carrier gas (e.g., nitrogen) and a vaporized component that is a solid or liquid at temperatures and pressures near ambient conditions (e.g., STP).

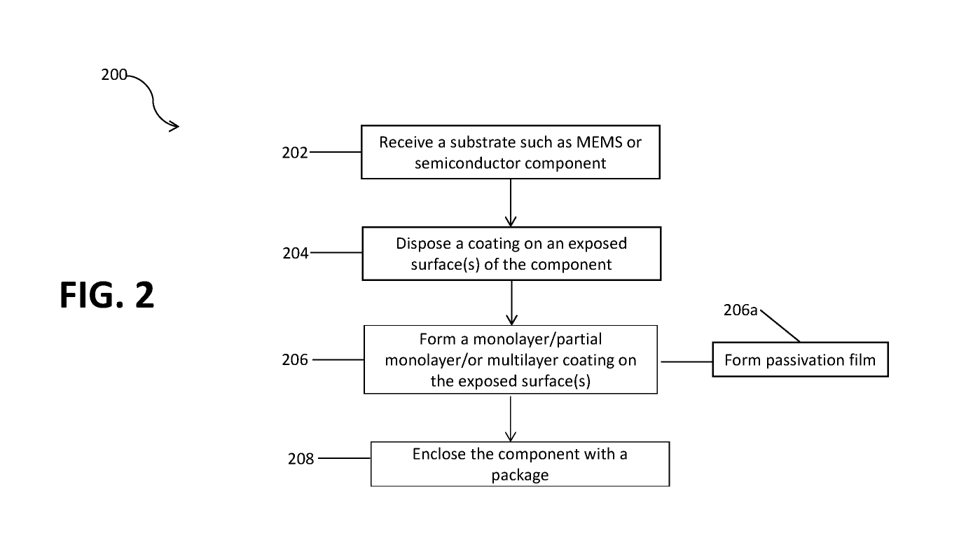

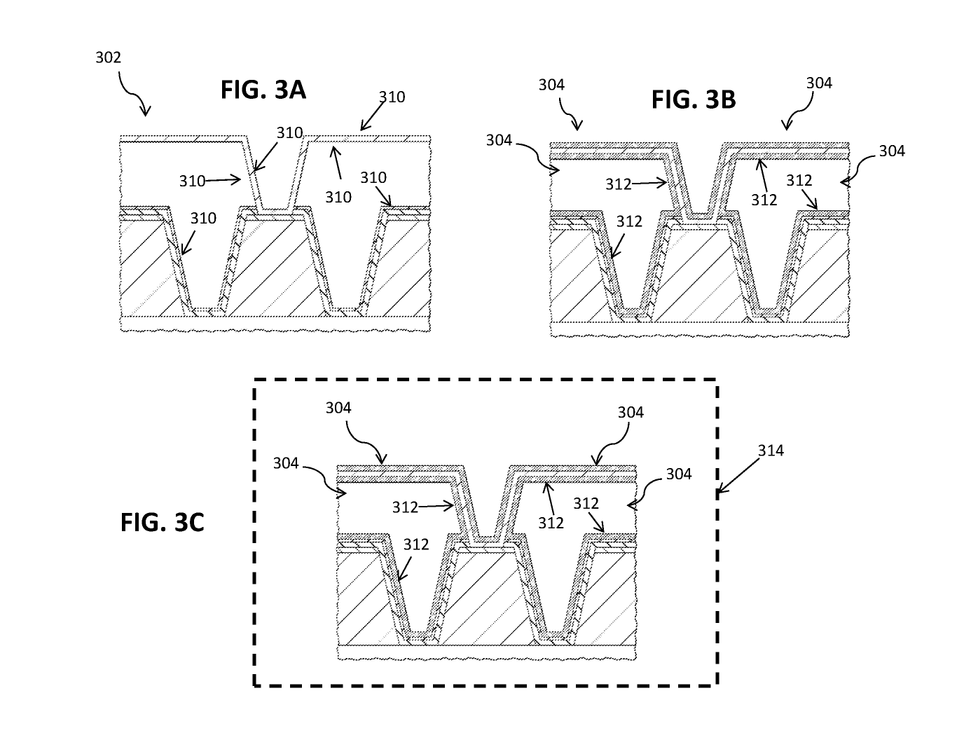

FIG. 2 is a flow chart of a method 200 of forming a passivation layer on a MEMS device component. FIGS. 3A through 3C are a sequence of partial side sectional views of a MEMS device component during fabrication according to the method 200. In the method 200, at block 202, a substrate is received in a chamber or apparatus to initiate the formation of the film on the MEMS device. The substrate at block 202 may include a MEMS wafer, another MEMS device component (such as a cap wafer), or a packaging component to package the MEMS device. FIGS. 3A through 3C show multiple exposed surfaces 310 of the substrate received at 302 as shown in FIG. 3A. At block 204 in the method 200, and as shown in FIG. 3B, a coating compound may be disposed on the substrate via a liquid and/or a vapor to form a monolayer, partial monolayer or multi-layer coating structure at block 206. For example, in FIGS. 3B and 3C, arrows 304 illustrate deposition of the coating compound 312 on the exposed surfaces 310.

In some examples, the introduction of the coating to the substrate at block 204 may cause a passivation layer to form at block 206a upon the coating's introduction to the substrate. Accordingly, at block 206a, in some examples, the passivation layer (e.g., a film) is formed via the exposure of the substrate to the liquid and/or vapor (e.g., as shown by the deposited coating compound 312 in FIGS. 3B and 3C), such that the substrate may undergo further processing including packaging and assembly, but the passivation layer can be formed before those steps and without further treatment of the substrate.

At block 208, a MEMS device is enclosed in a package 314, as shown in FIG. 3C. In an example where the substrate employed at block 202 in FIG. 2 is a MEMS device component, the block 208 may also include forming the assembly with another MEMS device component to create an equilibrium distribution of the passivation layer among the exposed surfaces of the one or more MEMS device components. In an example where the substrate at block 202 is a MEMS device package, the enclosure of a MEMS device in the package 314 at block 208 distributes the coating disposed at block 204 on multiple exposed surfaces of the MEMS device.

The coating compound may be capable of forming a monolayer or self-assembled monolayers (SAMs) at the device surface based on the nature of the compounds. In some examples, to form a monolayer or SAM at block 206, the coating compound may be exposed to the surface, and the ionic head group of the molecule may bond/interact to the MEMS and/or semiconductor surface in an orientation that points its hydrophobic tail section away from the surface. Van der Waals and dispersion forces can cause the tails to adopt a closely packed orientation upon a sufficient molecular density on the surface. For some coating compounds, substantially all of the molecules may align this way to give a nearly crystalline order. Some molecules may interact with other molecules instead of the surface. Also, the composition of the hydrophobic tail section may affect the packing efficiency of the monolayer. The misalignments and secondary molecular interactions may create an imperfect SAM-like coating on the surface of the MEMS and/or semiconductor component surface. As used herein, the term monolayer may refer to a SAM, a SAM-like layer or other monolayer.

After the MEMS surfaces are coated with a sufficiently dense layer of the coating compound, the surface energies can be reduced, and the incidence of adherence may be reduced or eliminated.

To deposit a thin film layer or a coating on a surface of a MEMS or semiconductor component, any suitable method may be used for enabling the exposed surfaces 310 of FIG. 3A to be coated with the liquid and/or vapor at block 204 of FIG. 2, as illustrated by arrows 304 of FIGS. 3B and 3C. Possible techniques include an evaporative deposition process, a spin-on or spray on process, or any other suitable techniques. In evaporative deposition, evaporated material condenses on a substrate to form a layer. In spin-on, spray-on or dip-on deposition, a coating material is applied, usually from a solvent solution of the coating material, and the solvent is subsequently evaporated to leave the coating material on the substrate.

In any of the application processes used at block 204, the surface of the MEMS and/or semiconductor component should be exposed to the coating compound for a time sufficient to form a coating or layer (e.g., a monolayer). The time may be in the range of minutes to hours. The resulting thin film may vary in thickness from about 3 angstroms (Å) to about 1,000 Å. For any process, monolayer formation can be verified by measuring liquid contact angles on a test surface. After the coating has been applied, the MEMS and/or semiconductor component may be enclosed and/or sealed within a package or larger container at block 208 (as shown in FIG. 3C).

The disposition of the coating compound on the surface of the MEMS component and/or semiconductor component at block 204 may result in a thin layer of material that can be damaged or displaced due to impact or wear created by the interaction of the various moving components. Such contact may occur in MEMS and/or semiconductor components with contacting surfaces that are subject to frequent contact in use and a large number of contacts during the product lifetime, such as in optical modulators (e.g., a SLM, an RF switch, etc.). In at least one example, the particular coating compound or combination of coating compounds may be selected for a portion of the coating compound is vaporized to form a vapor or gas within the processing region during normal operation of the device. The ability of the coating compound to form a vapor or gas is dependent on a coating compound equilibrium partial pressure, which varies as a function of the temperature (e.g., expected operating temperature range) of the coating compound, the pressure of the region surrounding the coating compound, the coating compound bond strength to internal surfaces of the processing region, and the coating compound molecular weight. For example, the coating compound may be configured to allow a MEMS and/or semiconductor component to operate at a temperature ranging from about −50° C. to about 150° C., or about 0° C. to about 100° C. In another example, the coating compound may be selected based, at least in part, on its ability to diffuse along a surface of the MEMS and/or semiconductor component within the processing region. In this example, one or more surfaces of the MEMS and/or semiconductor component, or package in which the component is contained, may be treated to act as wetting surfaces for the coating compound. In this way, the coating compound may be mobile to allow a replacement coating compound to flow into any damaged layer of the coating compound.

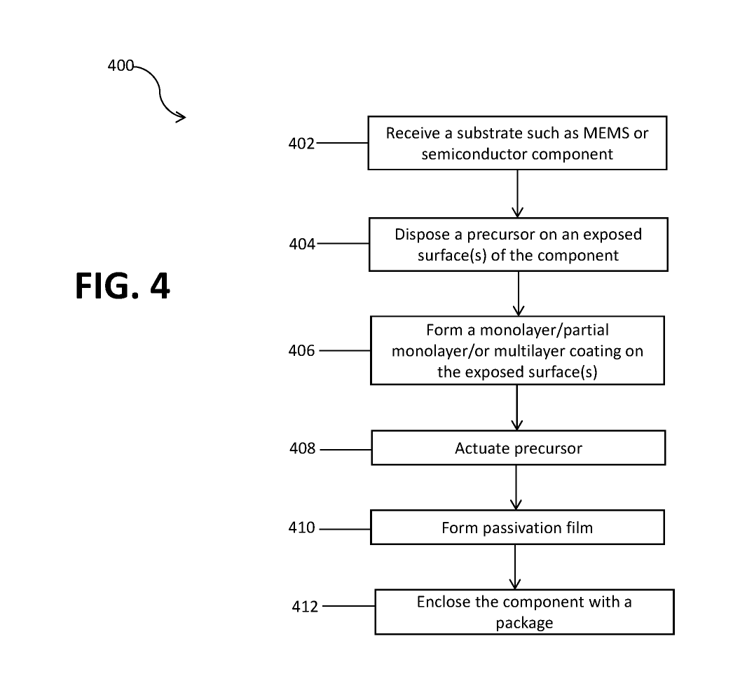

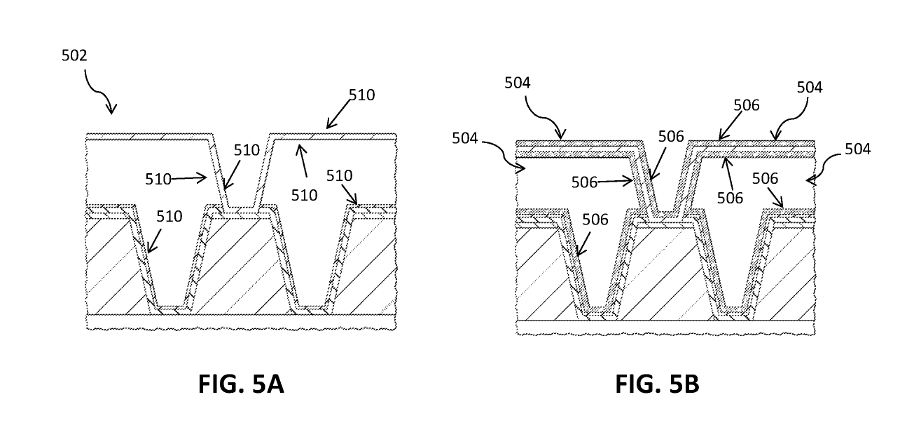

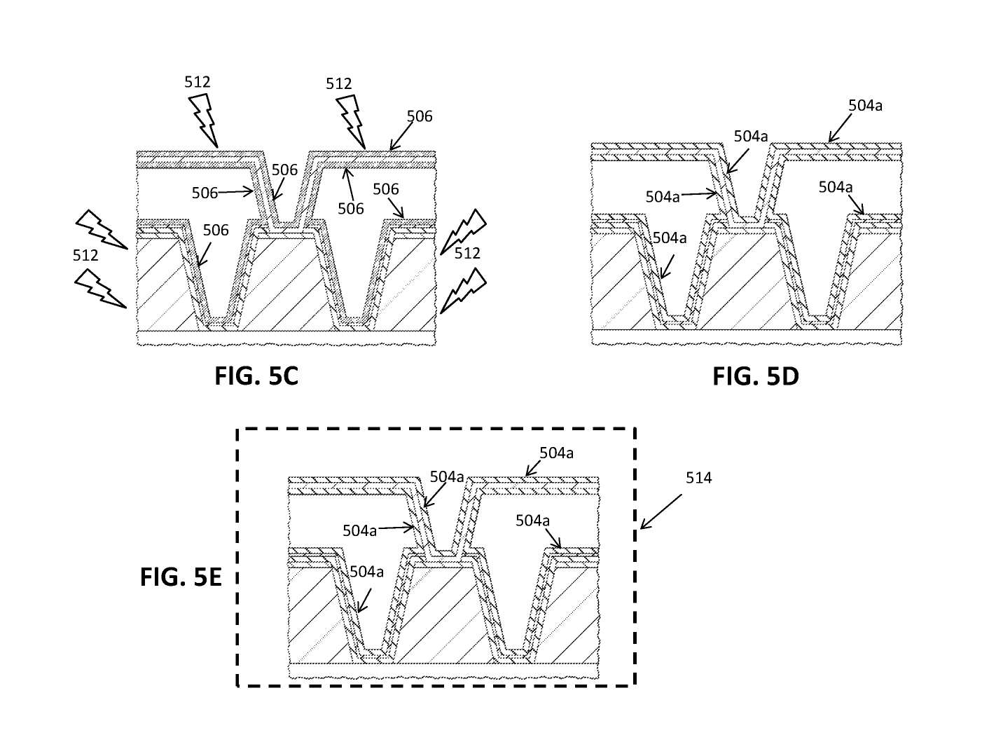

FIG. 4 is a flow chart of a first alternative method 400 of forming a passivation layer on a MEMS device component. FIGS. 5A through 5E are a sequence of partial side sectional views of a MEMS device component during fabrication according to the method 400. At block 402, a substrate is received in a chamber or apparatus to initiate the formation of the film on the MEMS device. The substrate at block 402 may include a MEMS wafer, another MEMS device component (such as a cap wafer), or a packaging component to package the MEMS device. FIG. 5A shows multiple exposed surfaces 510 of the substrate received at 502. At block 404 of FIG. 4, a coating compound may be disposed on the substrate via a liquid and/or a vapor to form a monolayer, partial monolayer, or multi-layer coating structure at block 406. For example, in FIG. 5B, arrows 504 illustrate deposition of the coating compound on the exposed surfaces 510 to form a precursor layer 506 (block 406 of FIG. 4). Accordingly, the deposited coating compound may include a precursor, and it may form a thin layer on the MEMS and/or semiconductor component, irrespective of whether the coating compound is formed on a portion of a surface of a MEMS and/or semiconductor component, over an entire surface, and/or contained within a larger package.

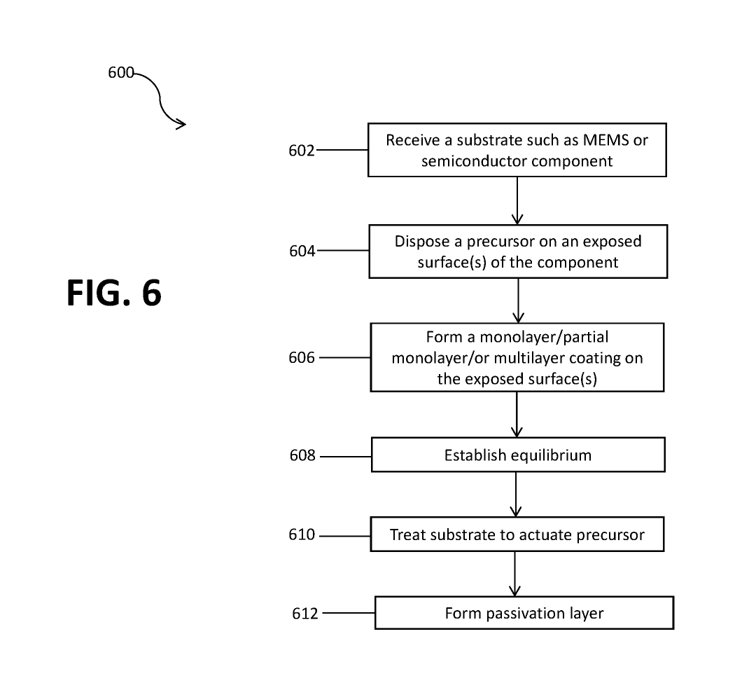

At block 408 of FIG. 4, the precursor layer 506 is actuated, as illustrated by emphasis bolts 512 in FIG. 5C. At block 410 of FIG. 4, in response to such actuation of the precursor layer 506 at block 408, the precursor layer 506 (as shown in FIGS. 5B and 5C) forms a passivation layer 504a (as shown in FIGS. 5D and 5E). For example, the transformation of the precursor at block 408 may be a thermal actuation via annealing, a radiation based process (such as a photochemical process/reaction), or an electrochemical process/reaction, such as via the actuation of the device comprising the substrate. In an example where the substrate employed at block 402 is a MEMS device component, block 412 may also comprise forming the assembly with another MEMS device component to create an equilibrium distribution of the passivation layer among the exposed surfaces of the one or more MEMS device components, as discussed in detail with respect to FIG. 6 below. In an example where the substrate at block 402 is a MEMS device package 514 as shown in FIG. 5E, the enclosure of a MEMS device in the package at block 412 in FIG. 4 distributes the coating disposed at block 404 on multiple exposed surfaces of the MEMS device, as is discussed in further detail in herein.

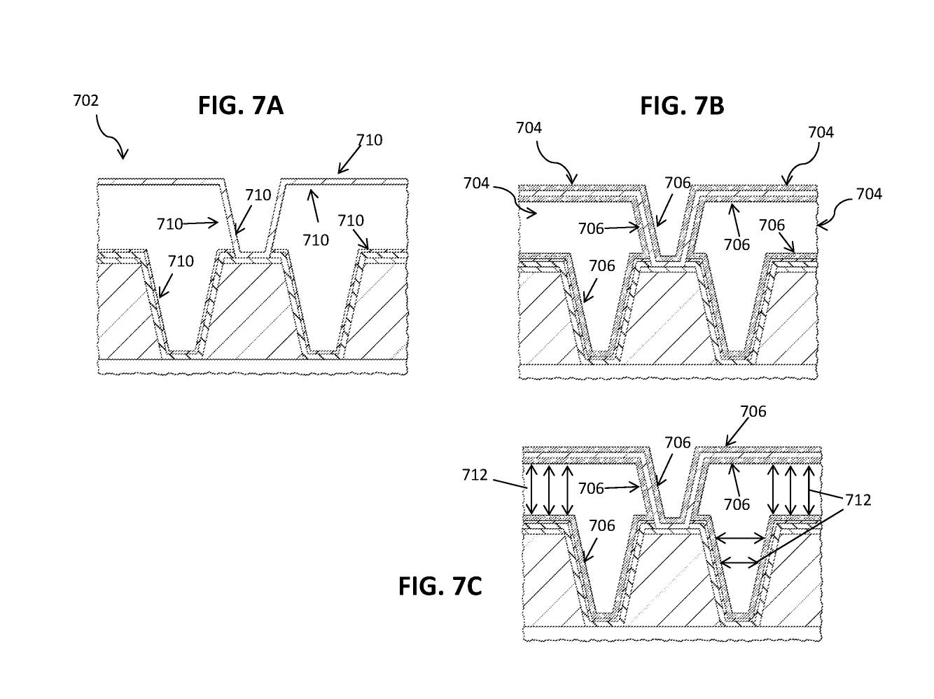

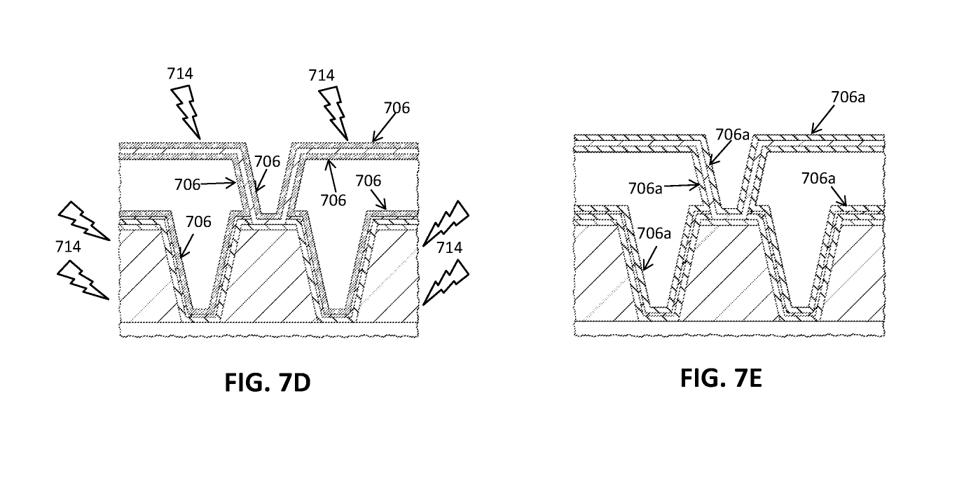

FIG. 6 is a flow chart of an alternative method 600 of forming a passivation layer on a MEMS device. FIGS. 7A-7E are a series of partial schematic illustrations of the method 600. At block 602 in FIG. 6, a substrate is received in a chamber or apparatus to initiate the formation of the film on the MEMS device. FIG. 7A illustrates the plurality of exposed surfaces 710 of the substrate. The substrate employed at 702 (and block 602 in FIG. 6) may comprise a MEMS wafer, another MEMS device component (such as a cap wafer), or a packaging component to package the MEMS device. At block 604 in FIG. 6 and 704 in FIG. 7B, a precursor 706 may be disposed on the substrate via a liquid and/or a vapor to form a monolayer of precursor 706 as shown in FIG. 7C. This monolayer of the precursor 706 may be a partial monolayer or multi-layer coating structure, as shown in FIG. 7C and at block 606 in FIG. 6. This is illustrated in FIG. 7B via the plurality of arrows 704 showing the precursor's 706 deposition on the plurality of exposed surfaces 710 in FIG. 7A. In one example, the precursor 706 comprises a long-chain alcohol of at least 12 carbons. At block 608 of FIG. 6, an equilibrium distribution of the precursor 706 is established on the exposed surface(s) of the MEMS device component, as illustrated by arrows 712 in FIG. 7C. While the precursor 706 is shown to be on the plurality of exposed surfaces in FIG. 7B, in some embodiments, it may be on less than all of the exposed surfaces so an equilibrium distribution as shown in FIG. 7C may occur. At block 610, as illustrated by emphasis bolts 714 in FIG. 7D, the MEMS device component is treated to form a passivation layer 706a (FIG. 7E) at block 612 (FIG. 6), so the passivation layer 706a is formed on the surface of the MEMS device component where the precursor layer 706 was deposited at block 604.

The example embodiments described herein may benefit devices other than the specific MEMS and/or semiconductor devices described herein. For example, embodiments described herein are useful in other MEMS, NEMS, larger scale actuators or sensors, or other comparable devices that experience stiction or other similar problems.

In at least one example, a method of manufacturing a MEMS device component includes: exposing a first MEMS device component to a vapor; and forming, subsequent to the vapor exposure, a passivation layer on at least one exposed surface of the component, wherein the vapor includes a bulk dielectric constant of at least 4.02. In some examples, the vapor includes a bulk dielectric constant of at least 40.2. In a further example, the method further includes treating the MEMS device subsequent to exposure to the vapor treatment, wherein the passivation layer is formed in response to the treating, and wherein the treating is via an at least one device via a heat treatment, a photochemical treatment or an electrochemical treatment. In at least one example, the heat treatment cycle is an annealing cycle under vacuum, and the electrochemical treatment includes actuating the MEMS device. In some examples, the vapor includes a bulk electrochemical window from −2.0 volts vs. SCE cathodic to 1.5 volts vs. SCE anodic.

In an alternative example, a method of manufacturing a MEMS device includes: exposing a MEMS device component to a vapor; and forming, subsequent to the vapor exposure, a passivation layer on at least one exposed surface of the MEMS device component, wherein the passivation layer includes a compound including at least one amino acid. In some examples, the amino acid includes L-leucine or N-alkyl glycine, and the vapor may include N-Methyl-2-pyrrolidone (NMP), propylene carbonate, and/or at least one of benzonitrile (C₆H₅CN) or tetramethylene sulfone ((CH₂)₄SO₂). In further examples, subsequent to the vapor exposure, the compound is heated and forms the passivation layer in response to the treating, wherein the treating includes: at least one device actuation via use, a heat treatment, a photochemical treatment or an electrochemical treatment. In some examples, the passivation layer formed includes an alkyl nitrile. In one example, an alkyl group of the alkyl nitrile includes between 1-10 carbons.

In another example, a method of manufacturing a MEMS device includes: disposing a precursor in contact with at least a portion of a surface of a MEMS device component, wherein the precursor includes a long-chain alcohol of at least 12 carbons; establishing an equilibrium distribution of the precursor on the surface of the MEMS device component; treating the MEMS device component; forming a passivation layer on the surface of the MEMS device component, wherein the precursor is transformed into the passivation layer in response to the treating, and the passivation layer is formed on the surface of the MEMS device component including the precursor. In some examples, the treating includes at least one of a thermal, a photochemical or an electrochemical treatment, and the thermal treatment includes at least one annealing cycle under vacuum. In one example, the long-chain alcohol includes cetyl alcohol. In another example, the long-chain alcohol includes at least one heteroatom. In some cases, before disposing the precursor, the MEMS device component is treated to dehydrate the MEMS device component and evaporates water, such as by heating the MEMS device component in a vacuum chamber. In further cases, the method includes enclosing the assembly within a package after disposing the precursor on the at least one surface.

In an alternative example, a method of manufacturing a MEMS device includes: exposing at least one contact surface of a MEMS device component to an organic compound including at least one ionic region and at least one hydrophobic region; actuating the organic compound in contact with the at least one contact surface of the MEMS device component; and forming, in response to the actuation, a passivation film on the at least one contact surface. In some examples, the method further includes, subsequent to exposing the at least one contact surface, sealing the MEMS device component in a package.

In another example, a MEMS device includes: a MEMS component including a surface; a passivation layer on at least a portion of the surface, wherein the passivation layer includes a compound including an alkyl nitrile. The MEMS component includes at least one of an actuator, a motor, an RF switch, a sensor, a variable capacitor, an optical modulator, a microgear, an accelerometer, a transducer, a fluid nozzle, a gyroscope, a digital micromirror device or any combination thereof. In an example, the alkyl nitrile includes leucine. In a further example, the passivation layer is formed from a precursor that includes N-methyl pyrrolidinone (N-methyl butyrolactam), N-octyl pyrrolidinone (N-octyl butyrolactam), or propylene carbonate.

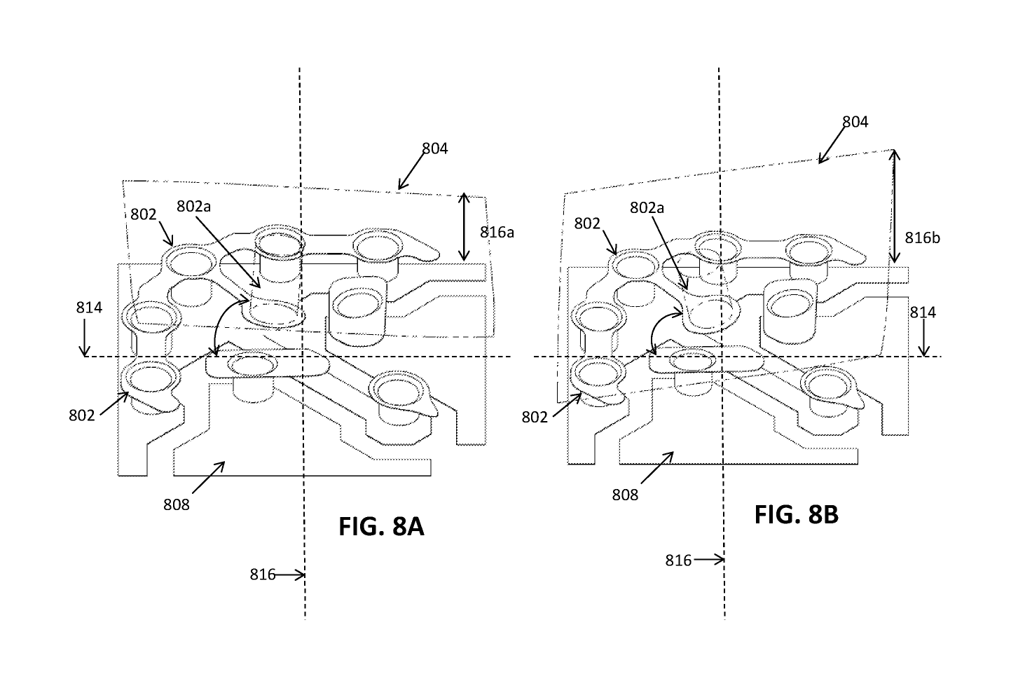

FIGS. 8A and 8B are perspective views of a first MEMS device component fabricated according to example embodiments. In the example of FIGS. 8A and 8B, the MEMS device component is a tilt-and-roll pixel (“TRP”) digital micromirror device (“DMD”), which includes a base structure 808 and multiple protrusions 802 extending from the base structure 808. At least one protrusion 802a (of the protrusions 802) is a pivotable support structure attached to a movable top micromirror structure (“movable element”) 804.

In FIG. 8A, the movable element 804 has a first orientation, so a first edge of the movable element 804 is spaced apart from a first edge of the base 808 by a distance 816a. After the protrusion 802a pivots to change the movable element 804 from the first orientation of FIG. 8A to a second orientation of FIG. 8B: (a) the first edge of the movable element 804 is spaced apart from the first edge of the base 808 by a distance 816b, as measured along an axis 816, which is greater than the distance 816a; and (b) in comparison to the first orientation of FIG. 8A, the movable element 804 has a different angle relative to an axis 814.

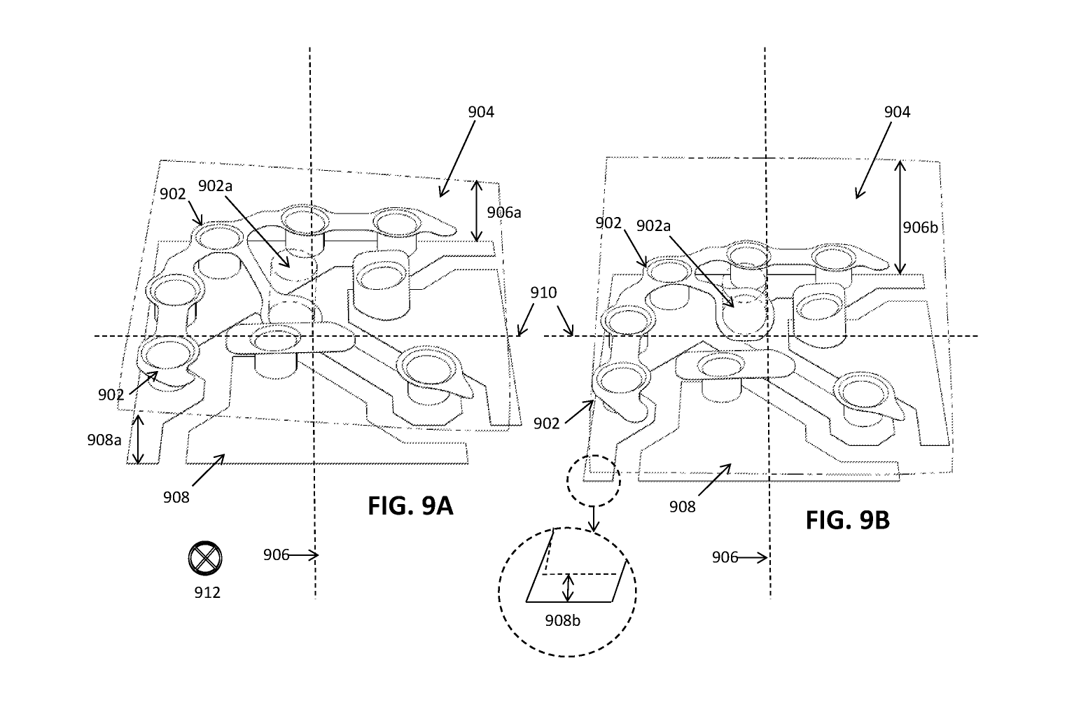

FIGS. 9A and 9B are perspective views of a second MEMS device component fabricated according to example embodiments. In the example of FIGS. 9A and 9B, the MEMS device component is another TRP digital micromirror device (“DMD”), which includes a base structure 908 and multiple protrusions 902 extending from the base structure 908. At least one protrusion 902a (of the protrusions 902) is a pivotable support structure attached to a movable top micromirror structure (“movable element”) 904.

In FIG. 9A, the movable element 904 has a first orientation, so: (a) a first corner of the movable element 904 is spaced apart from a first corner of the base 908 by a distance 906a as measured along an axis 906; and (b) a second opposite corner of the movable element 904 is spaced apart from a second opposite corner of the base 908 by a distance 908a. An axis 912 is illustrated as being perpendicular to the axis 906 and the page plane, and an axis 910 is illustrated as being perpendicular to both axes 912 and 906. In various examples, the movable element 904 may be moved in a direction along this axis 912 instead of or in addition to other directions along the axes 906 and/or 910. After the protrusion 902a pivots to change the movable element 904 from the first orientation of FIG. 9A to a second orientation of FIG. 9B: (a) the first corner of the movable element 904 is spaced apart from the first corner of the base 908 by a distance 906b, which is greater than the distance 906a; and (b) the second opposite corner of the movable element 904 is spaced apart from the second opposite corner of the base 908 by a distance 908b, which is smaller than the distance 908a.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

What is claimed is:

1. A method of manufacturing a MEMS device, comprising:
exposing a first MEMS device component to a vapor; and
forming, subsequent to the vapor exposure, a passivation layer on at least one exposed surface of the component, wherein the vapor comprises a material having a bulk dielectric constant of at least 4.02.

2. The method of claim 1, wherein the vapor comprises material a bulk dielectric constant of at least 40.2.

3. The method of claim 1, further comprising treating the MEMS device subsequent to exposure to the vapor treatment, wherein the passivation layer is formed in response to the vapor treating.

4. The method of claim 1, wherein the treating is via an at least one device via a heat treatment, a photochemical treatment or an electrochemical treatment.

5. The method of claim 4, wherein the heat treatment cycle is an annealing cycle under vacuum and wherein the electrochemical treatment comprises actuating the MEMS device.

6. The method of claim 1, wherein the vapor comprises a solvent that has a bulk electrochemical window from −2.0 volts vs. SCE cathodic to 1.5 volts vs. SCE anodic.

7. The method of claim 1, wherein the vapor further comprises N-Methyl-2-pyrrolidone (NMP) or propylene carbonate.

8. The method of claim 1, wherein the vapor further comprises at least one of benzonitrile (C₆H₅CN) or tetramethylene sulfone ((CH₂)₄SO₂).

9. A method of manufacturing a MEMS device, comprising:
exposing a MEMS device component to a vapor; and
forming, subsequent to the vapor exposure, a passivation layer on at least one exposed surface of the MEMS device component, wherein the passivation layer comprises a compound comprising at least one amino acid.

10. The method of claim 9, wherein the amino acid comprises L-leucine or N-alkyl glycine.

11. The method of claim 9, further comprising, subsequent to the vapor exposure, treating the compound and forming the passivation layer in response to the treating, wherein the treating comprises: at least one device actuation via use, a heat treatment, a photochemical treatment or an electrochemical treatment.

12. The method of claim 9, wherein the passivation layer comprises an alkyl nitrile.

13. The method of claim 12, wherein an alkyl group of the alkyl nitrile comprises between 1-10 carbons.

14. A method of manufacturing a MEMS device, comprising:
disposing a precursor in contact with at least a portion of a surface of a MEMS device component, wherein the precursor comprises a long-chain alcohol of at least 12 carbons;
establishing an equilibrium distribution of the precursor on the surface of the MEMS device component;
treating the MEMS device component; and
forming a passivation layer on the surface of the MEMS device component, wherein the precursor is transformed into the passivation layer in response to the treating, and the passivation layer is formed on the surface of the MEMS device component comprising the precursor.

15. The method of claim 14, wherein the treating comprises at least one of a thermal, a photochemical, or an electrochemical treatment.

16. The method of claim 15, wherein the thermal treatment comprises at least one annealing cycle under vacuum.

17. The method of claim 14, wherein the long-chain alcohol comprises cetyl alcohol.

18. The method of claim 14, wherein the long-chain alcohol comprises at least one heteroatom.

19. The method of claim 14, further comprising, before disposing the precursor, treating the MEMS device component to dehydrate the MEMS device component and evaporate water.

20. The method of claim 19, wherein treating the MEMS device component to dehydrate includes heating the MEMS device component in a vacuum chamber.

21. The method of claim 14, further comprising enclosing the assembly within a package after disposing the precursor on the at least one surface.

22. A method of manufacturing a MEMS device, comprising:
exposing at least one contact surface of a MEMS device component to an organic compound comprising at least one ionic region and at least one hydrophobic region;
actuating the organic compound in contact with the at least one contact surface of the MEMS device component; and
forming, in response to the actuation, a passivation film on the at least one contact surface.

23. The method of claim 22, further comprising, subsequent to exposing the at least one contact surface, sealing the MEMS device component in a package.

24. A MEMS device comprising:
a MEMS component comprising a surface; and
a passivation layer on at least a portion of the surface, wherein the passivation layer comprises a compound comprising an alkyl nitrile.

25. The device of claim 24, wherein the MEMS component comprises at least one of an actuator, a motor, an RF switch, a sensor, a variable capacitor, an optical modulator, a microgear, an accelerometer, a transducer, a fluid nozzle, a gyroscope, a digital micromirror device or any combination thereof.

26. The device of claim 24, wherein the alkyl nitrile comprises leucine.

27. The device of claim 24, wherein the passivation layer is formed from a precursor that comprises N-methyl pyrrolidinone (N-methyl butyrolactam), N-octyl pyrrolidinone (Nd octyl butyrolactam), or propylene carbonate.

28. A method of manufacturing a MEMS device, comprising:
exposing a MEMS device component to a vapor; and
forming, subsequent to the vapor exposure, a passivation layer on at least one exposed surface of the MEMS device component, wherein the passivation layer comprises at least one antioxidant compound.
